(19) United States
(12) Patent Application Publication
(10) Pub. No.: US 2026/0210705 A1
(43) Pub. Date: Jul. 23, 2026

(54) APPARATUS FOR ALIGNMENT AND TESTING, AND METHOD FOR ALIGNMENT AND TESTING

(71) Applicant: SAMSUNG ELECTRONICS CO., LTD., Suwon-si (KR)

(72) Inventor: Heejin CHOI, Suwon-si (KR)

(73) Assignee: SAMSUNG ELECTRONICS CO., LTD., Suwon-Si (KR)

(21) Appl. No.: 19/419,616

(22) Filed: Dec. 15, 2025

(30) Foreign Application Priority Data
Jan. 21, 2025 (KR) 10-2025-0008848

(51) Int. Cl. G01B 11/27; G01M 11/08

(52) U.S. Cl. CPC G01B 11/272; G01M 11/08

(57) ABSTRACT

An apparatus for alignment and testing may include: a light source configured to emit light; a photodetector configured to receive the light; an optical coupler connected to the light source and the photodetector, the optical coupler including a first channel and a second channel; a switch configured to set a propagation direction of the light; a first probe connected to the switch; and a second probe connected to the switch, wherein the first channel is configured for aligning the first probe with an input coupler of a photonic integrated circuit, and the second probe with an output coupler of the photonic integrated circuit, and wherein the second channel is configured for testing the photonic integrated circuit by measuring a portion of the light that is input to the first probe and then provided to the second channel via the second probe.

### CROSS-REFERENCE TO RELATED APPLICATION

This application is based on and claims priority under 35 U.S.C. §119 to Korean Patent Application No. 10-2025-0008848, filed on January 21, 2025, in the Korean Intellectual Property Office, the disclosure of which is incorporated by reference herein in its entirety.

### BACKGROUND

### 1. Field

Some embodiments of the present disclosure relate to an apparatus for alignment and testing and a method for alignment and testing.

### 2. Description of Related Art

In a photonic integrated circuit (PIC), light is input and output through a grating coupler or an edge coupler, and for effective optical input and output, accurate alignment between optical fiber and optical input/output terminals is required.

Currently, individual sensors are placed near probe fibers to accurately align the probe fibers with optical input/output terminals of PICs. However, when the input/output terminals of PICs are arranged very close together, or when package structures such as microlenses are disposed on PICs, interference may occur between the sensors and the package structures, and it becomes necessary to calibrate the relative positions between the probe fibers and the sensors.

### SUMMARY

According to some embodiments of the present disclosure, an apparatus for aligning probes and testing photonic integrated circuits (PICs), and a method of aligning probes and testing PICs, may be provided.

According to some embodiments of the present disclosure, an apparatus for alignment and testing may include: a light source configured to emit light; a photodetector configured to receive the light; an optical coupler connected to the light source and the photodetector, the optical coupler including a first channel and a second channel; a switch configured to set a propagation direction of the light; a first probe connected to the switch; and a second probe connected to the switch, wherein the first channel is configured for aligning the first probe with an input coupler of a photonic integrated circuit, and the second probe with an output coupler of the photonic integrated circuit, and wherein the second channel is configured for testing the photonic integrated circuit by measuring a portion of the light that is input to the first probe and then provided to the second channel via the second probe.

According to some embodiments of the present disclosure, the optical coupler may be configured to split the light emitted from the light source into a reference path and a measurement path.

According to some embodiments of the present disclosure, the apparatus may further include a mirror, wherein the mirror is along the reference path and is configured to reflect the light emitted from the light source.

According to some embodiments of the present disclosure, the photodetector may be configured to measure interference signals between a portion of the light along the reference path and a portion of the light along the measurement path.

According to some embodiments of the present disclosure, the light source may be configured to perform continuous wavelength scanning in an original band (O-band) ranging from 1,270 nm to 1,340 nm or in a conventional and long-wavelength band (C&L band) ranging from 1525 nm to 1,610 nm.

According to some embodiments of the present disclosure, the switch may be configured to select the propagation direction of the light toward the first probe or the second probe.

According to some embodiments of the present disclosure, the switch may be configured to set the propagation direction of the light towards the first probe to align the first probe with the input coupler of the photonic integrated circuit, and then towards the second probe to align the second probe with the output coupler of the photonic integrated circuit.

According to some embodiments of the present disclosure, the switch may include a splitter, a first polarization rotator, and a second polarization rotator.

According to some embodiments of the present disclosure, the first polarization rotator may be configured to rotate polarization of the light emitted from the light source such that the light passes through the splitter.

According to some embodiments of the present disclosure, the first polarization rotator may be configured to rotate polarization of the light emitted from the light source such that the light is reflected by the splitter.

According to some embodiments of the present disclosure, the second polarization rotator may be configured to adjust polarization of the light emitted from the light source such that the light does not return to the light source.

According to some embodiments of the present disclosure, the first probe may be configured to measure a distance to the input coupler of the photonic integrated circuit by using a principle of optical frequency domain reflectometry (OFDR).

According to some embodiments of the present disclosure, a method for alignment and testing may include: splitting, by an optical coupler, light from a light source into a reference path and a measurement path; aligning a first probe with an input coupler of a photonic integrated circuit and a second probe with an output coupler of the photonic integrated circuit by measuring, through a first channel of a photodetector, interference signals between a portion of the light along the reference path and a portion of the light along the measurement path; and testing the photonic integrated circuit through a second channel of the photodetector.

According to some embodiments of the present disclosure, the aligning may include: setting, via a switch, a propagation direction of the light towards the first probe to align the first probe with the input coupler of the photonic integrated circuit, and then setting, via the switch, the propagation direction of the light towards the second probe to align the second probe with the output coupler of the photonic integrated circuit.

According to some embodiments of the present disclosure, the switch may include a splitter, a first polarization rotator, and a second polarization rotator, and wherein the first polarization rotator may be configured to rotate polarization of the light from the light source such that the light passes through the splitter.

According to some embodiments of the present disclosure, the switch may include a splitter, a first polarization rotator, and a second polarization rotator, and wherein the first polarization rotator may be configured to rotate polarization of the light from the light source such that the light is reflected by the splitter.

According to some embodiments of the present disclosure, the switch may include a splitter, a first polarization rotator, and a second polarization rotator, and wherein the second polarization rotator is configured to adjust the light such that the light does not propagate to the light source.

According to some embodiments of the present disclosure, the aligning may include reflecting the light from the light source by a mirror along the reference path.

According to some embodiments of the present disclosure, the testing may include measuring, via the second channel, the light, wherein the light is provided to the second channel by the light traveling to the input coupler via the first probe, and then to the second probe via the output coupler.

According to some embodiments of the present disclosure, the first probe may be configured to measure a distance to the input coupler of the photonic integrated circuit by using a principle of optical frequency domain reflectometry (OFDR).

Additional aspects will be set forth in part in the description which follows and, in part, will be apparent from the description, or may be learned by practice of the presented example embodiments of the present disclosure.

### BRIEF DESCRIPTION OF DRAWINGS

The above and other aspects, features, and advantages of certain embodiments of the present disclosure will be more apparent from the following description taken in conjunction with the accompanying drawings, in which:

FIG. 1 is a view illustrating an apparatus for alignment and testing according to an embodiment;

FIG. 2 is a view illustrating the principle of optical frequency domain reflectometry (OFDR);

FIG. 3 is a view illustrating an optical coupler according to an embodiment;

FIG. 4 is a view illustrating how a probe is aligned with a coupler of a photonic integrated circuit (PIC) according to an embodiment;

FIGS. 5A and 5B are views illustrating a switch according to an embodiment; and

FIG. 6 is a flowchart illustrating a method for alignment and testing according to an embodiment.

### DETAILED DESCRIPTION

Reference will now be made in detail to non-limiting example embodiments of the present disclosure, examples of which are illustrated in the accompanying drawings, wherein like reference numerals refer to like elements throughout. In this regard, embodiments of the present disclosure may have different forms and should not be construed as being limited to the descriptions set forth herein. Accordingly, the example embodiments are merely described below, by referring to the figures, to explain example aspects. As used herein, the term “and/or” includes any and all combinations of one or more of the associated listed items.

Hereinafter, an apparatus and method for alignment and testing will be described according to various embodiments with reference to the accompanying drawings. In the drawings, like reference numbers refer to like elements, and also the size of each element may be exaggerated for clarity of illustration. The embodiments described herein are for illustrative purposes only, and various modifications may be made therefrom.

In the following description, when an element is referred to as being “above” or “on” another element, it may be directly on the other element while making contact with the other element or may be above the other element without making contact with the other element. The terms of a singular form may include plural forms unless otherwise mentioned. It will be further understood that the terms “comprises” (or “includes”) and/or “comprising” (or “including”) used herein specify the presence of stated features or elements, but do not preclude the presence or addition of one or more other features or elements.

An element referred to with a definite article or a demonstrative determiner may be construed as the element or the elements even though it has a singular form. Operations of a method may be performed in any appropriate order unless explicitly described in terms of order or described to the contrary, and are not limited to the stated order thereof.

Furthermore, line connections or connection members between elements depicted in the drawings represent functional connections and/or physical or circuit connections by way of example, and in actual applications, they may be replaced or embodied with various additional functional connections, physical connections, or circuit connections.

Examples and terms are just used herein to describe example technical aspects and should not be considered for purposes of limitation.

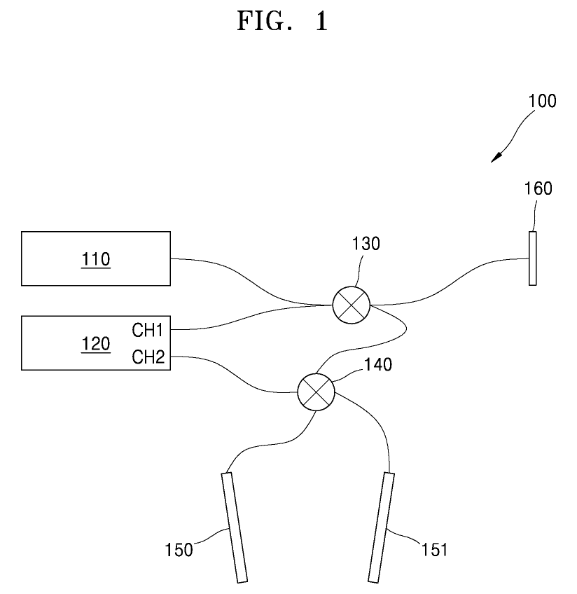

FIG. 1 is a view illustrating an apparatus 100 for alignment and testing according to an embodiment.

Referring to FIG. 1, the apparatus 100 for alignment and testing may include a light source 110 configured to emit light, a photodetector 120 configured to receive light, an optical coupler 130 connected to the light source 110 and the photodetector 120, a switch 140 connected to the optical coupler 130 and configured to set the propagation direction of light, and a first probe 150 and a second probe 151 connected to the switch 140.

The light source 110 may be a tunable wavelength light source capable of tuning the wavelength of light emission. The light source 110 may emit a plurality of laser beams, and among the laser beams, laser beams that have mutual optical coherence may be incident on the optical coupler 130. The light source 110 may generate and output light in different wavelength bands. In addition, the light source 110 may generate and output pulsed light or continuous wave light. The light source 110 may include a laser diode (LD). The light source 110 may be capable of performing continuous wavelength scanning in an original band (O-band: about 1,270 nm to about 1,340 nm) or a conventional and long-wavelength band (C&L-band: about 1525 nm to about 1,610 nm).

The photodetector 120 may measure interference signals between light reflected from a reference path and light reflected from a measurement path. The reference path may be an optical path that provides a baseline or a reference signal for comparison with the measurement path. The reference path may be an optical path connected to a mirror 160 (described later). The measurement path may be an optical path used for interacting with a device under test (DUT).

The photodetector 120 may include a plurality of channels. The photodetector 120 may include a first channel CH1 and a second channel CH2.

The first channel CH1 may be used to align the DUT with the first probe 150 and the second probe 151. The DUT may be an input coupler or an output coupler of a photonic integrated circuit (PIC). That is, the first channel CH1 may be used to align the first probe 150 with the input coupler of the PIC, and to align the second probe 151 with the output coupler of the PIC. The first channel CH1 may measure interference signals by optical frequency domain reflectometry (OFDR).

The second channel CH2 may be used to test the PIC. The second channel CH2 may be used to test the PIC by measuring light that is input to the first probe 150 and then is provided to the second probe 151.

Because the photodetector 120 includes the first channel CH1 and the second channel CH2, the apparatus 100 for alignment and testing may have both the function of aligning the DUT with the first probe 150 and the second probe 151, and the function of testing the PIC.

The optical coupler 130 may split light emitted from the light source 110 into the reference path and the measurement path. The optical coupler 130 may split light emitted from the light source 110 into the reference path and the measurement path at a given ratio.

The optical coupler 130 may be a polarization maintaining (PM) coupler. The optical coupler 130 may divide a signal input through input ports at a fixed ratio and transmit the divided signal to output ports. Conversely, the optical coupler 130 may divide a signal input through the output ports at a fixed ratio and transmit the divided signal to the input ports.

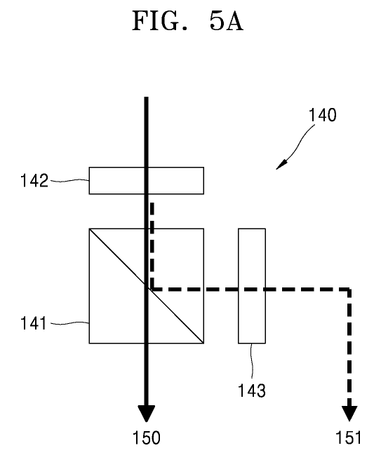

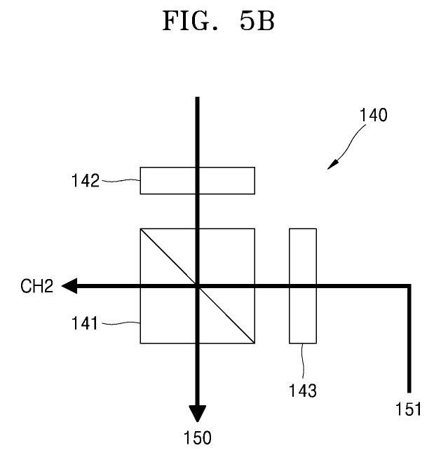

The switch 140 may select the propagation direction of light toward the first probe 150 or the second probe 151. The switch 140 may set the propagation direction of light to sequentially align the first probe 150 with the input coupler of the PIC and then the second probe 151 with the output coupler of the PIC. The switch 140 may distribute incident light and output light. The switch 140 may include a splitter, a first polarization rotator, and a second polarization rotator. The switch 140 is further described with reference to FIGS. 5A and 5B.

The first probe 150 may input light into the DUT. Light reflected from the DUT may be input into the first probe 150. The first probe 150 may perform a non-contact distance measuring sensor function for measuring the distance to the DUT. The first probe 150 may be aligned with the DUT. The first probe 150 may be aligned with the input coupler of the PIC. The first probe 150 may include an optical fiber.

The second probe 151 may be aligned with the DUT. The second probe 151 may be aligned with the output coupler of the PIC. The second probe 151 may include an optical fiber.

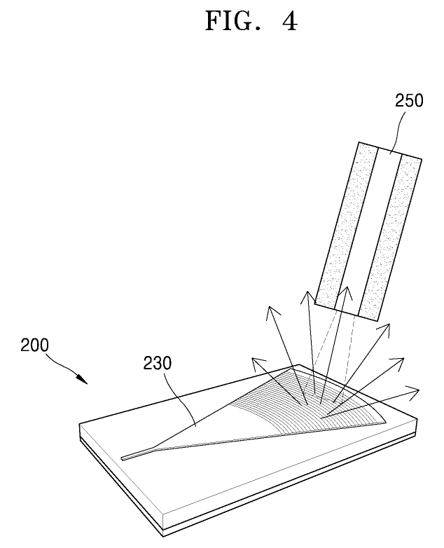

The alignment of the first probe 150 and the second probe 151 with the DUT is described below with reference to FIG. 4.

The apparatus 100 for alignment and testing may further include the mirror 160 disposed along the reference path and configured to reflect light emitted from the light source 110. The mirror 160 may include glass.

Light reflected from the DUT may return intact along an incident path of the light, interfere with a signal reflected from the mirror 160, and be measured through the first channel CH1 of the photodetector 120. Once the alignment of the first probe 150 with the input coupler of the PIC and the alignment of the second probe 151 with the output coupler of the PIC are completed, the reference path may be blocked, and thus, reflection signals are no longer generated. Then, light may be delivered only to the first probe 150 along the measurement path, the delivered light may then be provided to the input coupler of the PIC, then to the second probe 151 through the output coupler of the PIC, and then may be measured through the second channel CH2 of the photodetector 120.

According to the embodiment, the apparatus 100 for alignment and testing may measure the distance to the DUT and test the PIC by using the first probe 150 and the second probe 151 without requiring an additional sensor.

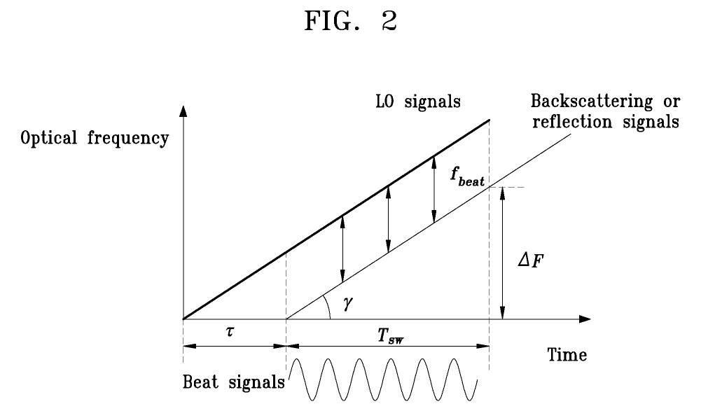

FIG. 2 is a view illustrating the principle of OFDR.

Local oscillator (LO) signals refer to the frequency of a local oscillator that is linearly swept over time, and backscattering or reflection signals refers to signals that are backscattered or reflected from an optical system under test. The frequency difference between the LO signals and the backscattered or reflection signals forms a beat frequency f_{beat} that is shown as a sine wave at the lower end of the graph in FIG. 2.

ΔF refers to a frequency difference corresponding to a time delay between the LO signals and the backscattered or reflection signals, τ refers to a time delay caused by an optical path difference between the LO signals and the backscattered or reflection signals, γ refers to a frequency sweep rate of a light source that is defined as the slope of the LO signals or the backscattered or reflection signals, and T_{sw} refers to the duration of the frequency sweep.

Light emitted from the light source 110 (refer to FIG. 1) may be split in two directions of an interferometer through the optical coupler 130 (refer to FIG. 1). Optical signals reflected from the DUT are time-delayed signals compared to optical signals from the reference path. The beat frequency f_{beat} of beat signals generated by interference between the optical signals reflected from the DUT and the optical signals from the reference path correlates with time delay.

Because time delay is proportional to the distance to the DUT, the location at which reflection signals are generated may be estimated by analyzing the beat frequency f_{beat} of the beat signals. Thus, the distance to the DUT may be measured using a probe without a sensor. For example, the first probe 150 (refer to FIG. 1) may measure the distance to the input coupler of the PIC by using the principle of OFDR, and the second probe 151 (refer to FIG. 1) may measure the distance to the output coupler of the PIC by using the principle of OFDR.

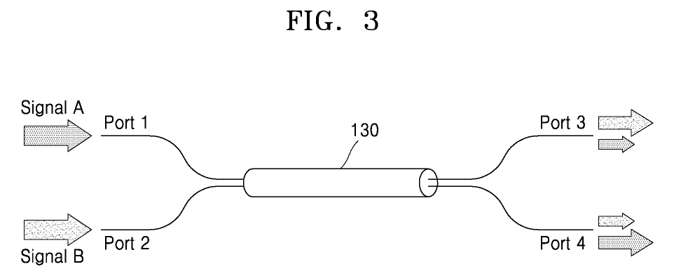

FIG. 3 is a view illustrating the optical coupler 130 according to an embodiment.

Referring to FIG. 3, the optical coupler 130 may include two input ports (ports 1 and 2) and two output ports (ports 3 and 4).

The optical coupler 130 may operate identically in both directions. A signal A may be split at a fixed ratio through the optical coupler 130 and delivered to the port 3 and the port 4. For example, the signal A may be split at a 50:50 ratio through the optical coupler 130 and delivered to the port 3 and the port 4. In another example, the signal A may be split at a 30:70 ratio through the optical coupler 130 and delivered to the port 3 and the port 4.

A signal B may also be split at a fixed ratio through the optical coupler 130 and delivered to the port 3 and the port 4. For example, the signal B may be split at a 50:50 ratio through the optical coupler 130 and delivered to the port 3 and the port 4. In another example, the signal B may be split at a 70:30 ratio through the optical coupler 130 and delivered to the port 3 and the port 4.

Similarly, signals entering through the output ports (the port 3 and the port 4) may be split at the same ratio and delivered to the port 1 and the port 2.

FIG. 4 is a view illustrating how a probe 250 is aligned with a coupler 230 of a PIC 200 according to an embodiment.

Referring to FIG. 4, the PIC 200 may include the coupler 230. The coupler 230 may include an input coupler or an output coupler. The coupler 230 may include a grating coupler.

The probe 250 and the coupler 230 of the PIC 200 may be aligned with each other to accurately control the distance between the probe 250 and the coupler 230. First, the probe 250 may be positioned near the coupler 230. Light may be input from the probe 250 toward the coupler 230, and a signal reflected from the coupler 230 may be measured. Arrows indicate signals reflected from the coupler 230 when the probe 250 and the coupler 230 of the PIC 200 are aligned with each other. The distance between the probe 250 and the coupler 230 may be measured by measuring reflected signals, and the probe 250 and the coupler 230 may be aligned with each other. In this case, the principle of OFDR may be used.

FIGS. 5A and 5B are views illustrating the switch 140 according to an embodiment.

FIG. 5A illustrates an operational principle of the switch 140 when the switch 140 aligns the first probe 150 with an input coupler of a PIC and the second probe 151 with an output coupler (not shown) of a PIC.

The alignment of the first probe 150 with the input coupler of the PIC and the alignment of the second probe 151 with the output coupler of the PIC may be sequentially performed by the switch 140.

The switch 140 may include a splitter 141, a first polarization rotator 142, and a second polarization rotator 143.

The splitter 141 may include a polarizing beamsplitter (PBS). The splitter 141 may control the reflection of light depending on the polarization of the light.

A polarization rotator may change the polarization direction of polarized light by a given angle (e.g., 45° or 90°). A polarization rotator may convert light from one polarization state (e.g., horizontal) into another polarization state (e.g., vertical) without changing the wavelength or intensity of the light.

The first polarization rotator 142 may rotate the polarization of light emitted from the light source 110 (refer to FIG. 1). The second polarization rotator 143 may rotate the polarization of light emitted from the light source 110 (refer to FIG. 1) toward the second channel CH2. The first polarization rotator 142 and the second polarization rotator 143 may set an optical path by controlling the polarization of light.

Arrows indicate propagation paths of light. The splitter 141 may split light into two orthogonal polarization components. P-polarized light, which is polarized parallel to the plane of incidence, may pass through the splitter 141 and be distributed to the first probe 150. When aligning the first probe 150 with the input coupler of the PIC, light proceeds in the direction of the solid arrow.

S-polarized light, which is polarized perpendicular to the plane of incidence, may be reflected at 90° by the splitter 141 and be distributed to the second probe 151. When aligning the second probe 151 with the output coupler of the PIC, light proceeds in the direction of the dashed arrow.

Light reflected from a DUT may return intact along an incident path of the light, interfere with a signal reflected from the mirror 160 (refer to FIG. 1), and be measured through the first channel CH1 of the photodetector 120 (refer to FIG. 1).

FIG. 5B illustrates an operational principle of the switch 140 when the PIC is tested.

The first polarization rotator 142 converts light from the light source 110 (refer to FIG. 1) into p-polarized light by rotating the polarization of the light, and thus, the light passes through the splitter 141. Light input into the first probe 150 may be provided to the second probe 151 via the PIC and may be measured through the second channel CH2 of the photodetector 120 (refer to FIG. 1). The second channel CH2 may be used to test the PIC by measuring light that is input to the first probe 150 and then provided to the second probe 151. The second polarization rotator 143 may adjust the polarization of light to be measured through the second channel CH2 such that the light may not return to the light source 110 (refer to FIG. 1).

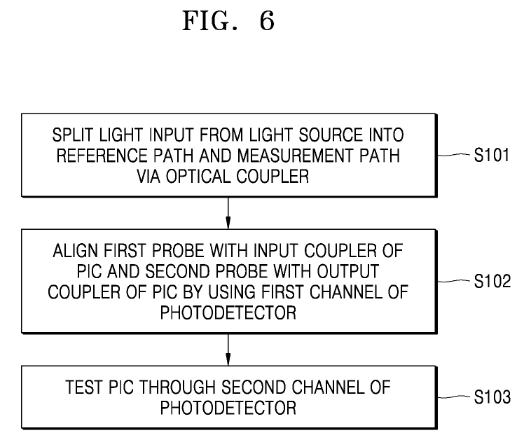

FIG. 6 is a flowchart illustrating a method for alignment and testing according to an embodiment.

Referring to FIG. 6, the method for alignment and testing may include: splitting light input from a light source into a reference path and a measurement path via an optical coupler (operation S101); aligning a first probe with an input coupler of a PIC, and a second probe with an output coupler of the PIC (operation S102); and testing the PIC through a second channel of a photodetector (operation S103).

Light input from the light source may be split into the reference path and the measurement path via the optical coupler (operation S101). The light may be input from the light source. The light source may be a tunable wavelength light source capable of tuning the wavelength of light emission.

The input light may be split into the reference path and the measurement path via the optical coupler. The input light may be split by the optical coupler into the reference path and the measurement path at a given ratio.

The first probe may be aligned with the input coupler of the PIC, and the second probe may be aligned with the output coupler of the PIC (operation S102). In the method for alignment and testing, the propagation direction of light may be set using a switch to sequentially align the first probe with the input coupler of the PIC and then the second probe with the output coupler of the PIC.

The switch may include a splitter, a first polarization rotator, and a second polarization rotator. The first polarization rotator may rotate the polarization of light emitted from the light source to allow the light to pass through the splitter. The first polarization rotator may rotate the polarization of light emitted from the light source to cause the light to be reflected by the splitter. The second polarization rotator may adjust light emitted from the light source to prevent the light from returning to the light source.

In the method for alignment and testing, light emitted from the light source may be reflected by a mirror provided along the reference path. Interference signals between light reflected from the mirror along the reference path and light reflected along the measurement path may be measured to align the first probe with the input coupler of the PIC, and the second probe with the output coupler of the PIC.

The aligning of the first probe with the input coupler of the PIC and the second probe with the output coupler of the PIC may be performed by measuring, through a first channel of the photodetector, interference signals between light reflected from the reference path and light reflected from the measurement path.

The first probe may measure the distance to the input coupler of the PIC by the OFDR principle.

The PIC may be tested through the second channel of the photodetector (S103). The second channel may be used to test the PIC by measuring light that is input through the first probe and then provided to the second probe.

As described above, according to an apparatus for alignment and testing and a method for alignment and testing of embodiments of the present disclosure, probe alignment and PIC testing may be carried out using the OFDR principle.

According to an apparatus for alignment and testing and a method for alignment and testing of embodiments of the present disclosure, the distance to a DUT may be measured using probes by the OFDR principle without requiring an additional sensor, and PICs may be tested. While the apparatus for alignment and testing and the method for alignment and testing have been described according to example embodiments with reference to the accompanying drawings, it will be understood by those of ordinary skill in the art that the present disclosure is not limited thereto, and that various modifications and other equivalent embodiments are included within the scope of the present disclosure. Therefore, the example embodiments described herein should be considered in a descriptive sense only and not for purposes of limitation. All differences within equivalent ranges of the scope of the present disclosure should be considered as being included in the scope of the present disclosure.

What is claimed is:

1. An apparatus for alignment and testing, the apparatus comprising:
a light source configured to emit light;
a photodetector configured to receive the light;
an optical coupler connected to the light source and the photodetector, the optical coupler comprising a first channel and a second channel;
a switch configured to set a propagation direction of the light;
a first probe connected to the switch; and
a second probe connected to the switch,
wherein the first channel is configured for aligning the first probe with an input coupler of a photonic integrated circuit, and the second probe with an output coupler of the photonic integrated circuit, and
wherein the second channel is configured for testing the photonic integrated circuit by measuring a portion of the light that is input to the first probe and then provided to the second channel via the second probe.

2. The apparatus of claim 1, wherein the optical coupler is configured to split the light emitted from the light source into a reference path and a measurement path.

3. The apparatus of claim 2, further comprising a mirror, wherein the mirror is along the reference path and is configured to reflect the light emitted from the light source.

4. The apparatus of claim 2, wherein the photodetector is configured to measure interference signals between a portion of the light along the reference path and a portion of the light along the measurement path.

5. The apparatus of claim 1, wherein the light source is configured to perform continuous wavelength scanning in an original band (O-band) ranging from 1,270 nm to 1,340 nm or in a conventional and long-wavelength band (C&L band) ranging from 1525 nm to 1,610 nm.

6. The apparatus of claim 1, wherein the switch is configured to select the propagation direction of the light toward the first probe or the second probe.

7. The apparatus of claim 1, wherein the switch is configured to set the propagation direction of the light towards the first probe to align the first probe with the input coupler of the photonic integrated circuit, and then towards the second probe to align the second probe with the output coupler of the photonic integrated circuit.

8. The apparatus of claim 1, wherein the switch comprises a splitter, a first polarization rotator, and a second polarization rotator.

9. The apparatus of claim 8, wherein the first polarization rotator is configured to rotate polarization of the light emitted from the light source such that the light passes through the splitter.

10. The apparatus of claim 8, wherein the first polarization rotator is configured to rotate polarization of the light emitted from the light source such that the light is reflected by the splitter.

11. The apparatus of claim 8, wherein the second polarization rotator is configured to adjust polarization of the light emitted from the light source such that the light does not return to the light source.

12. The apparatus of claim 1, wherein the first probe is configured to measure a distance to the input coupler of the photonic integrated circuit by using a principle of optical frequency domain reflectometry (OFDR).

13. A method for alignment and testing, the method comprising:
splitting, by an optical coupler, light from a light source into a reference path and a measurement path;
aligning a first probe with an input coupler of a photonic integrated circuit and a second probe with an output coupler of the photonic integrated circuit by measuring, through a first channel of a photodetector, interference signals between a portion of the light along the reference path and a portion of the light along the measurement path; and
testing the photonic integrated circuit through a second channel of the photodetector.

14. The method of claim 13, wherein the aligning comprises:
setting, via a switch, a propagation direction of the light towards the first probe to align the first probe with the input coupler of the photonic integrated circuit, and then setting, via the switch, the propagation direction of the light towards the second probe to align the second probe with the output coupler of the photonic integrated circuit.

15. The method of claim 14, wherein the switch includes a splitter, a first polarization rotator, and a second polarization rotator, and
wherein the first polarization rotator is configured to rotate polarization of the light from the light source such that the light passes through the splitter.

16. The method of claim 14, wherein the switch includes a splitter, a first polarization rotator, and a second polarization rotator, and
wherein the first polarization rotator is configured to rotate polarization of the light from the light source such that the light is reflected by the splitter.

17. The method of claim 14, wherein the switch includes a splitter, a first polarization rotator, and a second polarization rotator, and
wherein the second polarization rotator is configured to adjust the light such that the light does not propagate to the light source.

18. The method of claim 15, the aligning comprises reflecting the light from the light source by a mirror along the reference path.

19. The method of claim 15, wherein the testing comprises measuring, via the second channel, the light, wherein the light is provided to the second channel by the light traveling to the input coupler via the first probe, and then to the second probe via the output coupler.

20. The method of claim 15, wherein the first probe is configured to measure a distance to the input coupler of the photonic integrated circuit by using a principle of optical frequency domain reflectometry (OFDR).
